(19) United States
(12) Patent Application Publication
(10) Pub. No.: US 2025/0169300 A1
(43) Pub. Date: May 22, 2025

(54) DISPLAY DEVICE

(71) Applicant: LG Display Co., Ltd., Seoul (KR)

(72) Inventor: Jeihyun LEE, Paju-si (KR)

(21) Appl. No.: 18/780,016

(22) Filed: Jul. 22, 2024

(30) Foreign Application Priority Data
Nov. 21, 2023 (KR) 10-2023-0161904

(51) Int. Cl. H10K 59/131; G09G 3/3233; H10K 59/121

(52) U.S. Cl. CPC H10K 59/131; G09G 3/3233; H10K 59/1213; G09G 2300/0819; G09G 2300/0842; G09G 2300/0861

(57) ABSTRACT

A display device according to one embodiment includes a first thin film transistor, a second thin film transistor, and a third thin film transistor each including a semiconductor layer, a gate electrode disposed on the semiconductor layer, and a first electrode and a second electrode that are disposed on the gate electrode. A connection between the semiconductor layer of the first thin film transistor and the semiconductor layer of the second thin film transistor differs from a connection between the semiconductor layer of the second thin film transistor and the semiconductor layer of the third thin film transistor.

### CROSS REFERENCE TO RELATED APPLICATION

The present application claims priority to Korean Patent Application No. 10-2023-0161904, filed Nov. 21, 2023, the entire contents of which is incorporated herein for all purposes by this reference.

### BACKGROUND

### Technical Field

The present disclosure relates to a display device, and more specifically, to a display device with improved reliability of an oxide thin film transistor.

### Description of the Related Art

As the information society develops, various demands for display devices for displaying images are increasing, and various types of display devices such as liquid crystal display (LCD) devices and organic light emitting diode (OLED) display devices are utilized.

A display device includes a plurality of pixels and a plurality of switching elements for driving and controlling the pixels. The switching elements may be formed of thin film transistors, and the thin film transistors are widely applied to both the pixels and integrated circuits. Recently, various research and development have been conducted to improve the performance and reliability of the thin film transistors.

### BRIEF SUMMARY

Embodiments of the present specification are directed to providing a display device to which a connection structure between thin film transistors is applied in consideration of the characteristics of each of thin film transistors of a pixel.

Various embodiments of the present specification is directed to minimize fluctuation of a threshold voltage by implementing connection between a transistor sensitive to the fluctuation of the threshold voltage and an adjacent transistor through a separate conductive layer different from a semiconductor layer.

Various embodiments of the present specification is directed to minimizing fluctuation of a threshold voltage by implementing connection between a transistor sensitive to the fluctuation of the threshold voltage and an adjacent transistor through a line located on a conductive layer having excellent hydrogen capture ability.

Various embodiments of the present specification are directed to providing a display device which can reduce the number of contact holes required for connection between transistors and simplifying a process by implementing connection between transistors not relatively sensitive to fluctuation of a threshold voltage.

The technical benefits of the present specification are not limited to the above-described benefits, and other technical benefits may be inferred from embodiments below.

To achieve the benefits, a display device according to one embodiment includes a first thin film transistor, a second thin film transistor, and a third thin film transistor each including a semiconductor layer, a gate electrode disposed on the semiconductor layer, and a first electrode and a second electrode that are disposed on the gate electrode, wherein connection between the semiconductor layer of the first thin film transistor and the semiconductor layer of the second thin film transistor differs from connection between the semiconductor layer of the second thin film transistor and the semiconductor layer of the third thin film transistor.

To achieve the benefits, a display device according to another embodiment includes a first thin film transistor, a second thin film transistor, and a third thin film transistor each including a semiconductor layer, a gate electrode disposed on the semiconductor layer, and a first electrode and a second electrode that are disposed on the gate electrode, wherein the semiconductor layer of the first thin film transistor and the semiconductor layer of the second thin film transistor are connected through a first connection line, the semiconductor layer of the second thin film transistor and the semiconductor layer of the third thin film transistor are connected through a second connection line, and a reflectance of the first connection line is lower than a reflectance of the second connection line.

Detailed matters of other embodiments are included in a detailed description and accompanying drawings.

In the display device according to the embodiments, it is possible to minimize the fluctuation of the threshold voltage by implementing the connection between the transistor sensitive to the fluctuation of the threshold voltage and the adjacent transistor through the separate conductive layer different from the semiconductor layer.

In addition, in the display device according to the embodiments, it is possible to minimize the fluctuation of the threshold voltage by implementing the transistor sensitive to the fluctuation of the threshold voltage and the line located on a conductive layer having excellent hydrogen collection ability for connection between the transistor and the adjacent transistor.

In addition, in the display device according to the embodiments, it is possible to reduce the number of contact holes required for connection between transistors and simplifying the process by implementing the connection between the transistors not relatively sensitive to the fluctuation of the threshold voltage through the line located coplanarly with the semiconductor layers of the transistors.

In addition, in the display device according to the embodiments, by implementing the transistor sensitive to the fluctuation of the threshold voltage and the adjacent transistor through the line located on the conductive layer having excellent hydrogen capture ability, it is possible to minimize the defects of the transistors and increase the lifetimes of the transistors, thereby implementing the low-power display device.

However, the effects obtainable from the present specification are not limited to the above-described effects, and other effects that are not mentioned will be able to be clearly understood by those skilled in the art to which the present specification pertains from the following description.

### BRIEF DESCRIPTION OF THE SEVERAL VIEWS OF THE DRAWINGS

FIG. 1 is a cross-sectional view of a display device according to a first embodiment.

FIG. 2 is a cross-sectional view of a display device according to a second embodiment.

FIG. 3 is a cross-sectional view of a display device according to a third embodiment.

FIG. 4 is a cross-sectional view of a display device according to a fourth embodiment.

FIG. 5 is a pixel circuit diagram of a display device according to a fifth embodiment.

FIG. 6 is a cross-sectional view of the display device according to FIG. 5.

FIG. 7 is a cross-sectional view of a modified example of the display device according to FIG. 6.

### DETAILED DESCRIPTION

Hereinafter, embodiments will be described with reference to the accompanying drawings.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

The same reference numerals indicate the same components. Scales of components illustrated in the drawings differ from the actual scale for convenience of description, and thus are not limited to the scales illustrated in the drawings.

In the specification, when a first component (or an area, a layer, a portion, or the like) is described as “on,” “connected,” or “coupled to” a second component, it means that the first component may be directly connected/coupled to the second component or a third component may be disposed therebetween.

The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular expression includes the plural expression unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings. For example, as long as “immediately” or “directly” is not used, one or more other portions may be positioned between two portions. The spatially relative terms “below or beneath,” “lower,” “above,” “upper,” and the like can be used to easily describe the correlation with one element or components and another element or components as shown in the drawings. The spatially relative terms should be understood as the terms including different directions of elements in use or operation in addition to the directions shown in the drawings. For example, in case of turning the element shown in the drawing upside down, an element described as being disposed “below” or “beneath” another element may be disposed “above” another element. Therefore, the exemplary term “below” may include both downward and upward directions.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

Features of various embodiments of the present specification can be coupled or combined partially or entirely, and various technological interworking and driving are possible, and the embodiments may be implemented independently of each other or implemented together in an associated relationship.

Hereinafter, a display device of the present specification will be described with reference to the accompanying drawings and embodiments as follows.

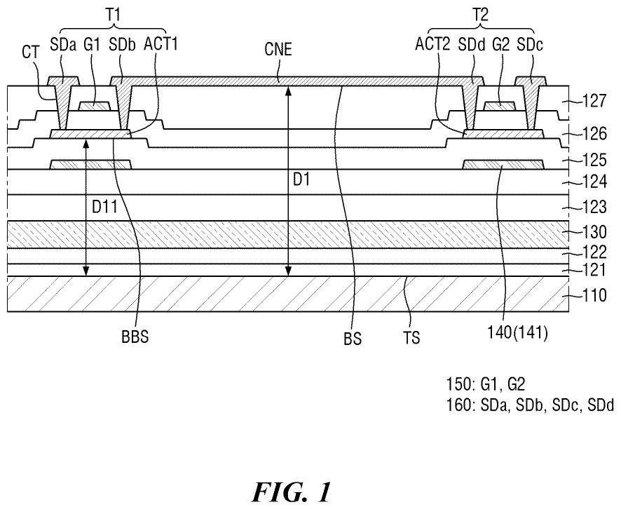

FIG. 1 is a cross-sectional view of a display device according to a first embodiment.

Referring to FIG. 1, the display device according to the present embodiment may include a substrate 110, a buffer layer 121 disposed on the substrate 110, a first insulating layer 122 disposed on the buffer layer 121, a first conductive layer 130 disposed on the first insulating layer 122, a second insulating layer 123 disposed on first conductive layer 130, a third insulating layer 124 disposed on the second insulating layer 123, a second conductive layer 140 disposed on the third insulating layer 124, a fourth insulating layer 125 disposed on the second conductive layer 140, a semiconductor layer disposed on the fourth insulating layer 125, a gate insulating layer 126 disposed on the semiconductor layer, a third conductive layer 150 disposed on the gate insulating layer 126, an interlayer insulating layer 127 disposed on the third conductive layer 150, and a fourth conductive layer 160 disposed on the interlayer insulating layer 127.

The substrate 110 may support each layer disposed thereon. The substrate 110 may be made of an insulating material such as a polymer resin. Examples of the polymer material may include polyethersulphone (PES), polyacrylate (PA), polyarylate (PAR), polyetherimide (PEI), polyethylene napthalate (PEN), polyethylene terepthalate (PET), polyphenylene sulfide (PPS), polyallylate, polyimide (PI), polycarbonate (PC), cellulose triacetate (CAT), cellulose acetate propionate (CAP), or combinations thereof. The substrate 110 may be a flexible substrate capable of bending, folding, rolling, and the like. An example of a material forming the flexible substrate may be polyimide (PI), but is not limited thereto. The substrate 110 may be a rigid substrate made of glass, quartz, or the like.

The buffer layer 121 may be disposed on the substrate 110. The buffer layer 121 may include an inorganic material. For example, the inorganic material may include silicon oxide (SiOx), silicon nitride (SiNx), or silicon oxynitride (SiOxNy), but is not limited thereto. The buffer layer 121 can prevent the diffusion of impurity ions and prevent the permeation of moisture or outside air. Unlike shown, the buffer layer 121 may include a plurality of layers. In other words, the buffer layer 121 may be formed of layers of silicon nitride (SiNx) and silicon oxide (SiOx) alternately stacked at least once.

A first insulating layer 122 may be disposed on the buffer layer 121. The first insulating layer 122 may contain an inorganic material. For example, the inorganic material may include silicon oxide (SiOx), silicon nitride (SiNx), or silicon oxynitride (SiOxNy), but is not limited thereto. Unlike shown, the first insulating layer 122 may include a plurality of layers. That is, the first insulating layer 122 may be provided as layers formed by alternately stacking silicon nitride (SiNx) and silicon oxide (SiOx) at least once.

The first conductive layer 130 may be disposed on the first insulating layer 122. The first conductive layer 130 may include a metal material. For example, the first conductive layer 130 may include a metal material having low reflectivity. For example, the first conductive layer 130 may include an opaque metal material. For example, the first conductive layer 130 may contain one or more selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). The first conductive layer 130 may include a light blocking layer, but is not limited thereto.

The second insulating layer 123 may be disposed on the first conductive layer 130. The second insulating layer 123 may include an inorganic material. For example, the inorganic material may include silicon oxide (SiOx), silicon nitride (SiNx), or silicon oxynitride (SiOxNy), but is not limited thereto. Unlike shown, the second insulating layer 123 may include a plurality of layers. That is, the second insulating layer 123 may be provided as layers formed by alternately stacking silicon nitride (SiNx) and silicon oxide (SiOx) at least once. For example, the second insulating layer 123 may perform an interlayer insulation function of insulating the first conductive layer 130 and the second conductive layer 140 to be described below.

The third insulating layer 124 may be disposed on the second insulating layer 123. The third insulating layer 124 may include an inorganic material. For example, the inorganic material may include silicon oxide (SiOx), silicon nitride (SiNx), or silicon oxynitride (SiOxNy), but is not limited thereto. Unlike shown, the third insulating layer 124 may include a plurality of layers. That is, the third insulating layer 124 may be provided as layers formed by alternately stacking silicon nitride (SiNx) and silicon oxide (SiOx) at least once. For example, the third insulating layer 124 may perform an interlayer insulation function of insulating the first conductive layer 130 and the second conductive layer 140 to be described below.

The second conductive layer 140 may be disposed on the third insulating layer 124. The second conductive layer 140 may include a light blocking layer 141. For example, the light blocking layer 141 may overlap semiconductor layers ACT1 and ACT2 of first and second transistors T1 and T2, which will be described below. The light blocking layer 141 may be disposed to overlap the semiconductor layers ACT1 and ACT2 of the first and second transistors T1 and T2, thereby blocking light traveling to the semiconductor layers ACT1 and ACT2 at the bottom. Although FIG. 1 shows that a width of the light blocking layer 141 is the same as widths of the semiconductor layers ACT1 and ACT2, the present disclosure is not limited thereto, and the width of the light blocking layer 141 may be greater than or smaller than the widths of the semiconductor layers ACT1 and ACT2. For example, the second conductive layer 140 may contain one or more selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). For example, the second conductive layer 140 may contain at least titanium (Ti). For example, the second conductive layer 140 may contain a material having excellent hydrogen (H2) capture ability. In the present specification, when any composition has a good hydrogen (H2) capture ability, it may mean that hydrogen (H2) may well permeate the corresponding composition. For example, titanium (Ti) may be a material having excellent hydrogen capture ability. For example, the hydrogen capture ability of the second conductive layer 140 may be better than that of the first conductive layer 130. More specifically, good hydrogen capture ability means that the bond between a target composition and hydrogen (H2) is an exothermic reaction, and hydrogen (H2) is not easily separated after bonding between the target composition and hydrogen (H2). In one embodiment, since the second conductive layer 140 has a better hydrogen capture ability than the first conductive layer 130 and the fourth conductive layer 160, heat of formation Ah of the second conductive layer 140 may be lower heat of formation Ah of the first conductive layer 130. Furthermore, a better hydrogen capture ability may mean that, in the case of a connection electrode formed from the corresponding conductive layer, fluctuation of threshold voltages (Vth) of thin film transistors electrically connected to the connection electrode is less.

The fourth insulating layer 125 may be disposed on the second conductive layer 140. The fourth insulating layer 125 may include an inorganic material. For example, the inorganic material may include silicon oxide (SiOx), silicon nitride (SiNx), or silicon oxynitride (SiOxNy), but is not limited thereto. Unlike shown, the fourth insulating layer 125 may include a plurality of layers. That is, the fourth insulating layer 125 may be provided as layers formed by alternately stacking silicon nitride (SiNx) and silicon oxide (SiOx) at least once. For example, the fourth insulating layer 125 may perform an interlayer insulation function of insulating the semiconductor layer to be described below and the second conductive layer 140.

The semiconductor layer may be disposed on the fourth insulating layer 125. The semiconductor layer may include the first semiconductor layer ACT1 of the first thin film transistor T1 and the second semiconductor layer ACT2 of the second thin film transistor T2. The semiconductor layers ACT1 and ACT2 may include oxide. The semiconductor layers ACT1 and ACT2 may be oxide semiconductor layers. The oxide semiconductor layer may have a lower reflectance of light than a semiconductor layer made of polycrystalline silicon. That is, the oxide semiconductor layer may have higher light transmittance than the semiconductor layer made of polycrystalline silicon. The semiconductor layers ACT1 and ACT2 may each include a channel area, a first area, and a second area. The channel areas the semiconductor layers ACT1 and ACT2 may overlap upper gate electrodes G1 and G2, respectively.

The oxide semiconductor may contain, for example, a binary compound (ABx), a ternary compound (ABxCy), or a quaternary compound (ABxCyDz) containing indium, zinc, gallium, tin, titanium, aluminum, hafnium (Hf), zirconium (Zr), magnesium (Mg), etc. In one embodiment, the second semiconductor layer 124 may contain ITZO (oxide containing indium, tin, and titanium) or IGZO (oxide containing indium, gallium, and tin).

The electrical conductivity of the first and second areas may be higher than those of the channel areas of the semiconductor layers ACT1 and ACT2. To this end, the first and second areas of the semiconductor layers ACT1 and ACT2 may each be electrically conductive.

The gate insulating layer 126 may be formed on the semiconductor layers ACT1 and ACT2. The gate insulating layer 126 may include an inorganic material. For example, the inorganic material may include silicon oxide (SiOx), silicon nitride (SiNx), or silicon oxynitride (SiOxNy), but is not limited thereto. Unlike shown, the gate insulating layer 126 may include a plurality of layers. That is, the gate insulating layer 126 may be provided as layers formed by alternately stacking silicon nitride (SiNx) and silicon oxide (SiOx) at least once. For example, the gate insulating layer 126 may serve to insulate the gate electrodes G1 and G2 and the semiconductor layer 140.

The third conductive layer 150 may be disposed on the gate insulating layer 126. The third conductive layer 150 may include the first gate electrode G1 of the first thin film transistor T1 and the second gate electrode G2 of the second thin film transistor T2. The gate electrodes G1 and G2 may overlap the channel areas of the semiconductor layers ACT1 and ACT2 of the thin film transistors T1 and T2, respectively. For example, the third conductive layer 150 may contain one or more selected from the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

The interlayer insulating layer 127 may be disposed on the third conductive layer 150. The interlayer insulating layer 127 may contain an inorganic material or an organic material. For example, the inorganic material may include silicon oxide (SiOx), silicon nitride (SiNx), or silicon oxynitride (SiOxNy), but is not limited thereto. Unlike shown, the interlayer insulating layer 127 may include a plurality of layers. That is, the interlayer insulating layer 127 may be provided as layers formed by alternately stacking silicon nitride (SiNx) and silicon oxide (SiOx) at least once. For example, the interlayer insulating layer 127 may serve to insulate the gate electrodes G1 and G2 and the fourth conductive layer 160 to be described below.

The fourth conductive layer 160 may be disposed on the interlayer insulating layer 127.

The fourth conductive layer 160 may include a first source electrode SDa and a first drain electrode SDb of the first thin film transistor T1, a second source electrode SDc and a second drain electrode SDd of the second thin film transistor T2, and a connection line CNE.

The fourth conductive layer 160 may contain at least any one among the group consisting of molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). The fourth conductive layer 160 may be a single film made of the above-exemplified materials. The present disclosure is not limited thereto, and the fourth conductive layer 160 may be a stacked film. For example, the fourth conductive layer 160 may be formed in a stacking structure of Ti/Al/Ti, Mo/Al/Mo, Mo/AlGe/Mo, Ti/Cu, etc.

The first source electrode SDa of the first thin film transistor T1 may be electrically connected to the first area of the first semiconductor ACT1 through a contact hole CT passing through the interlayer insulating layer 127 and the gate insulating layer 126.

The first drain electrode SDb of the first thin film transistor T1 may be electrically connected to the second area of the first semiconductor ACT1 through the contact hole CT passing through the interlayer insulating layer 127 and the gate insulating layer 126.

The second source electrode SDe of the first thin film transistor T2 may be electrically connected to the first area of the second semiconductor ACT2 through the contact hole CT passing through the interlayer insulating layer 127 and the gate insulating layer 126.

The second drain electrode SDd of the second thin film transistor T2 may be electrically connected to the second area of the second semiconductor ACT2 through the contact hole CT passing through the interlayer insulating layer 127 and the gate insulating layer 126.

The first thin film transistor T1 according to the first embodiment may include the channel area, the first electrode, the second electrode, and the first gate electrode G1. The channel area may be an area that overlaps the first gate electrode GI of the first semiconductor layer ACT1, the first electrode may be an area that overlaps and is in contact with the first source electrode SDa or the first source electrode SDa of the first semiconductor layer ACT1, and the second electrode may be an area (or a first area) that overlaps and is in contact with the first drain electrode SDb or the first drain electrode SDb of the first semiconductor layer ACT1. For example, the first thin film transistor T1 may include the first semiconductor layer ACT1, the first gate electrode G1, the first source electrode SDa, and the first drain electrode SDb.

The second thin film transistor T2 according to the first embodiment may include the channel area, the first electrode, the second electrode, and the second gate electrode G2. The channel area may be an area that overlaps the second gate electrode G2 of the second semiconductor layer ACT2, the first electrode may be an area that overlaps and is in contact with the second source electrode SDc or the second source electrode SDc of the second semiconductor layer ACT2, and the second electrode may be an area (or a first area) that overlaps and is in contact with the second drain electrode SDd or the second drain electrode SDd of the second semiconductor layer ACT2. For example, the second thin film transistor T2 may include the second semiconductor layer ACT2, the second gate electrode G2, the second source electrode SDc, and the second drain electrode SDd.

According to the first embodiment, the first thin film transistor T1 and the second thin film transistor T2 may be electrically connected. The first thin film transistor T1 and the second thin film transistor T2 may be connected through the connection line CNE. According to the present embodiment, the connection line CNE may be disposed on the fourth conductive layer 160. The connection line CNE may be disposed between the first drain electrode SDb and the second drain electrode SDd, and the first drain electrode SDb and the second drain electrode SDd may be electrically connected through the connection line CNE. The first drain electrode SDb and the second drain electrode SDd may each be directly connected to the connection line CNE. In some embodiments, the first drain electrode SDb of the first transistor T1 and the second drain electrode SDd of the second transistor T2 overlaps with the connection line CNE from a plan view (see FIGS. 1, 3, and 4). Here, the connection line CNE does not overlap with the electrode SDa of the first thin film transistor T1 and the electrode SDc of the second thin film transistor T2 from a plan view (scc FIGS. 1, 2, 3, and 4).

The display device according to the first embodiment shows that electrical connection between adjacent thin film transistors (in FIG. 1, the first and second thin film transistors T1 and T2) may be made through the connection line CNE located on the fourth conductive layer 160.

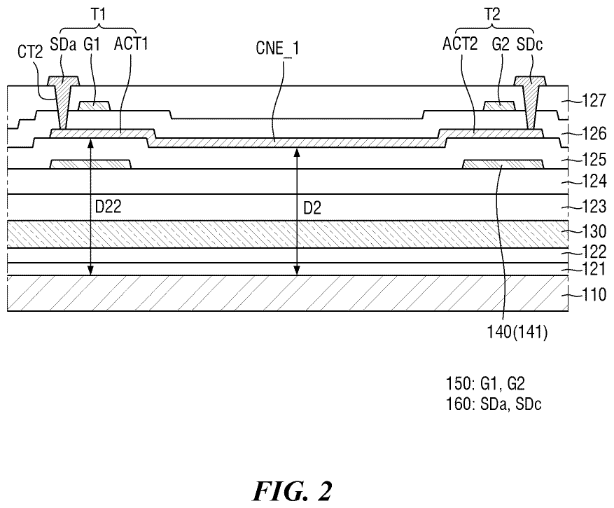

Hereinafter, other embodiments will be described. Embodiments according to FIGS. 2 to 4 below show the electrical connection relationship between adjacent thin film transistors. The embodiments according to FIGS. 2 to 4 show that the electrical connection between the thin film transistors may be made in different ways.

FIG. 2 is a cross-sectional view of a display device according to a second embodiment.

The display device according to FIG. 2 differs from the display device according to FIG. 1 in that a connection line CNE_1 is located on the semiconductor layer.

More specifically, in the case of the display device according to the second embodiment, the first drain electrode SDb (see FIG. 1) and the second drain electrode SDd (see FIG. 1) may be omitted. The second electrode of the first thin film transistor T1 of the display device according to the present embodiment may be a second area located at one side (area connected to the connection line CNE_1) of the channel area of the first semiconductor layer ACT1. In addition, the second electrode of the second thin film transistor T2 may be a second area located at the other side (area connected to the connection line CNE_1) of the channel area of the second semiconductor layer ACT2. The connection line CNE_1 may be located coplanarly with the first semiconductor layer ACT1 and the second semiconductor layer ACT2 and may contain the same material as the first semiconductor layer ACT1 and the second semiconductor layer ACT2. The connection line CNE_1 may be directly connected to the first and second semiconductor layers ACT1 and ACT2. The connection line CNE_1 may be electrically connected to the first and second semiconductor layers ACT1 and ACT2.

The connection line CNE_1 may be a conductive area like the first and second areas of the thin film transistors T1 and T2.

According to the display device according to the second embodiment, since the second area located at one side (area connected to the connection line CNE_1) of the channel area of the first semiconductor layer ACT1 and the second area located at the other side (area connected to the connection line CNE_1) of the channel area of the second semiconductor layer ACT2 serve as the second electrodes of the thin first semiconductor layers T1 and T2, respectively, the first drain electrode SDb (see FIG. 1) and the second drain electrode SDd (see FIG. 1) described above in FIG. 1 may be omitted. Furthermore, since the contact hole CT connecting the first drain electrode SDb with the second area of the first semiconductor layer ACT1 and the contact hole CT connecting the second drain electrode SDd and the second area of the second semiconductor layer ACT2 may be omitted, it is possible to simplify the process.

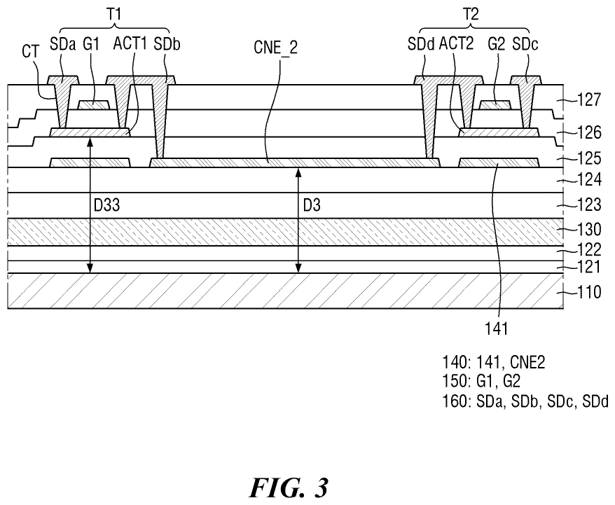

FIG. 3 is a cross-sectional view of a display device according to a third embodiment.

Referring to FIG. 3, the display device according to FIG. 3 differs from the display device according to FIG. 1 in that a connection line CNE_2 is located on the second conductive layer 140.

More specifically, in the case of the display device according to the third embodiment, the first drain electrode SDb of the first transistor T1 may be electrically connected to the connection line CNE_2 through the contact hole CT, and the second drain electrode SDd of the second thin film transistor T2 may be electrically connected to the connection line CNE_2 through the contact hole CT. The connection line CNE_2 may be located coplanarly with the light blocking layer 141 and may contain the same material and formed during the same manufacturing process as the light blocking layer 141.

According to the display device according to the third embodiment, since the connection line CNE_2 is located on the second conductive layer 140, it is possible to secure a sufficient space in which the connection line CNE_2 may be disposed compared to the first embodiment in which the connection line CNE is located on the fourth conductive layer 160.

In addition, since the reflectance of the second conductive layer 140 is higher than that of the semiconductor layer, it is possible to prevent the phenomenon in which light enters the connection line CNE_2 and travels inside the connection line CNE_2, thereby preventing a change in characteristics of the first and second thin film transistors due to light and degradation of reliability thereof.

In addition, as described above in FIG. 1, since the second conductive layer 140 has better hydrogen capture ability than the first conductive layer 130 and the fourth conductive layer 160, when the first and second thin film transistors T1 and T2 are electrically connected by using the connection line CNE_2 located on the second conductive layer 140, it is possible to minimize fluctuation of the threshold voltages (Vth) of the first and second thin film transistors T1 and T2.

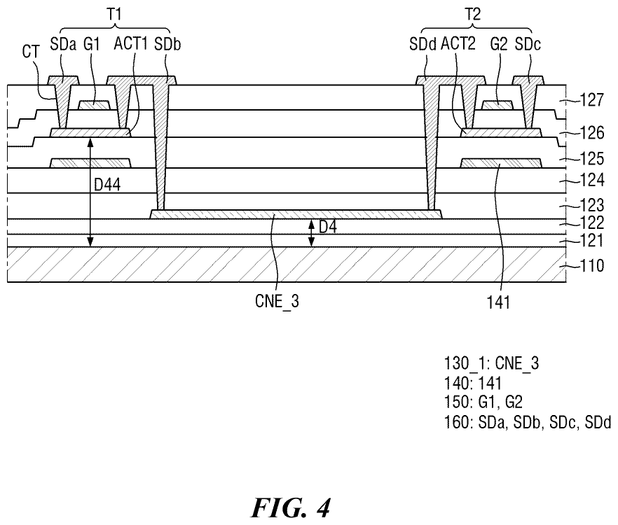

FIG. 4 is a cross-sectional view of a display device according to a fourth embodiment.

Referring to FIG. 4, the display device according to FIG. 4 differs from the display device according to FIG. 3 in that a connection line CNE_3 is located on a first conductive layer 130_1.

More specifically, in the case of the display device according to the fourth embodiment, the first drain electrode SDb of the first transistor T1 may be electrically connected to the connection line CNE_3 through the contact hole CT, and the second drain electrode SDd of the second thin film transistor T2 may be electrically connected to the connection line CNE_3 through the contact hole CT. The connection line CNE_3 may be located on the first conductive layer 130_1 and may include the same material as the first conductive layer 130_1.

According to the display device according to the fourth embodiment, since the connection line CNE_3 is located on the first conductive layer 130_1, it is possible to secure a sufficient space in which the connection line CNE_3 may be disposed compared to the first embodiment in which the connection line CNE_3 is located on the fourth conductive layer 160.

In addition, since the reflectance of the first conductive layer 130 is higher than that of the semiconductor layer, it is possible to prevent the phenomenon in which light enters the connection line CNE_3 and travels inside the connection line CNE_3, thereby preventing a change in characteristics of the first and second thin film transistors T1 and T2 due to light and degradation of reliability thereof.

As shown in FIGS. 1, 2, 3, and 4, the connection line CNE, CNE_1, CNE_2, CNE_3 is on the substrate 110 and between the first thin film transistor T1 and the second thin film transistor T2 from a plan view. The connection line electrically connects the first thin film transistor T1 and the second thin film transistor T2. Further, the connection line and the substrate 110 are spaced apart from each other by varying distances.

For example, in FIG. 1, the connection line CNE and the substrate 110 are spaced apart from each other by a first distance D1. More specifically, the first distance DI is defined by a distance between a bottom surface BS of the connection line CNE and a top surface TS of the substrate 110.

In FIG. 2, the connection line CNE_1 and the substrate 110 are spaced apart from each other by a second distance D2. More specifically, the second distance D2 is defined by a distance between a bottom surface BS of the connection line CNE_1 and a top surface TS of the substrate 110.

In FIG. 3, the connection line CNE_2 and the substrate 110 are spaced apart from each other by a third distance D3. More specifically, the third distance D3 is defined by a distance between a bottom surface BS of the connection line CNE_2 and a top surface TS of the substrate 110.

In FIG. 4, the connection line CNE_3 and the substrate 110 are spaced apart from each other by a fourth distance D4. More specifically, the fourth distance D4 is defined by a distance between a bottom surface BS of the connection line CNE_3 and a top surface TS of the substrate 110.

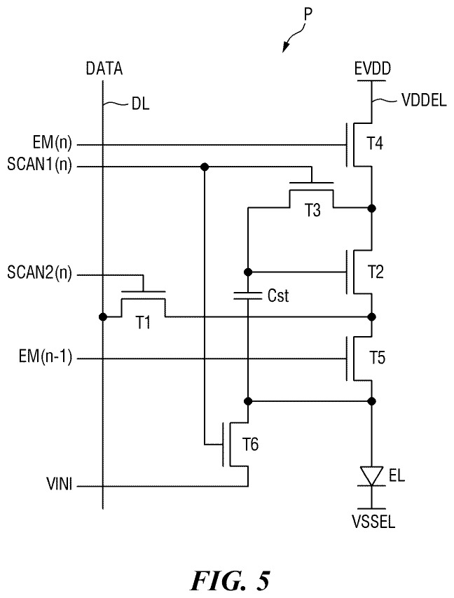

In some embodiments, a light emitting element EL is electrically connected to the first thin film transistor T1 and the second thin film transistor T2. In some embodiments, as shown in FIG. 5, the light emitting element EL may be electrically connected to the thin film transistors T1, T2, T3, T4, T5, and T6.

As illustrated in FIGS. 1, 2, 3, and 4, the semiconductor layer (e.g., ACT1, ACT2) and the substrate 110 are spaced apart from each other by varying distances.

For example, in FIG. 1, the semiconductor layer ACT1 and the substrate 110 are spaced apart from each other by a distance D11. More specifically, the distance D11 is defined by a distance between a bottom surface BBS of the semiconductor layer ACT1 and a top surface TS of the substrate 110. As shown distances D11 and DI are different from each other. In the embodiment of FIG. 1, distance DI is greater than distance D11.

In FIG. 2, the semiconductor layer ACT1 and the substrate 110 are spaced apart from each other by a distance D22. More specifically, the distance D22 is defined by a distance between a bottom surface BBS of the semiconductor layer ACT1 and a top surface TS of the substrate 110. As shown distances D22 and D2 are different from each other. In the embodiment of FIG. 2, distance D22 is greater than distance D2. Here, both the semiconductor layer ACT1 and the connection line CNE_1 both are on the same layer. Namely, both the semiconductor layer ACT1 and the connection line CNE_1 are on the fourth insulating layer 125. However, the distance D2 is smaller than distance D22 such that the bottom surface BS of the connection line CNE_1 is closer to the top surface TS of the substrate 110 compared to the bottom surface BBS of the semiconductor layer ACT1.

In FIG. 3, the semiconductor layer ACT1 and the substrate 110 are spaced apart from each other by a distance D33. More specifically, the distance D33 is defined by a distance between a bottom surface BBS of the semiconductor layer ACT1 and a top surface TS of the substrate 110. As shown distances D33 and D3 are different from each other. In the embodiment of FIG. 3, distance D33 is greater than distance D3.

In FIG. 4, the semiconductor layer ACT1 and the substrate 110 are spaced apart from each other by a distance D44. More specifically, the distance D44 is defined by a distance between a bottom surface BBS of the semiconductor layer ACT1 and a top surface TS of the substrate 110. As shown distances D44 and D4 are different from each other. In the embodiment of FIG. 4, distance D44 is greater than distance D4.

Hereinafter, a display device (fifth embodiment) having a pixel circuit diagram having a 6TIC structure will be described. For convenience of description, although it is exemplified that the pixel of the display device according to the fifth embodiment is 6TIC, the present disclosure is not limited thereto, and the pixel of the display device according to the fifth embodiment may have various pixel circuit diagrams such as 3TIC, 6T2C, 7TIC, 7T2C, 8TIC, and 8T2C. That is, FIG. 5 exemplarily shows the pixel circuit diagram for description, and the present disclosure is not limited thereto as long as a structure may control the light emission of a light emitting element EL by receiving the emission signal EM(n). For example, the pixel circuit may include an additional scan signal, a switching thin film transistor connected to the additional scan signal, and a switching thin film transistor to which an additional initialization voltage is applied, and the connection relationship of the switching elements or a connection position of a capacitor may be disposed variously. Hereinafter, for convenience of description, a display apparatus having the pixel circuit structure of FIG. 5 will be described.

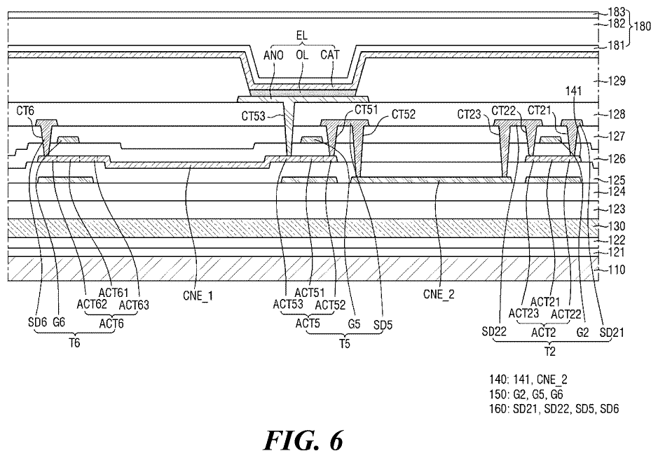

FIG. 5 is a pixel circuit diagram of a display device according to a fifth embodiment. FIG. 6 is a cross-sectional view of the display device according to FIG. 5.

Referring to FIGS. 5 and 6, each of the plurality of pixels P may include first to sixth thin film transistors T1 to T6, a capacitor CST, and the light emitting element EL connected to a pixel circuit.

The pixel circuit may drive the light emitting element EL by controlling a driving current flowing in the light emitting element EL. The pixel circuit may include the first to sixth transistors T1 to T6 and the capacitor CST. Each of the thin film transistors T1 to T6 may include a first electrode, a second electrode, and a gate electrode. One of the first electrode and the second electrode may be a source electrode, and the other may be a drain electrode.

Each of the thin film transistors T1 to T6 may be a p-type thin film transistor or an n-type thin film transistor. In the embodiment of FIG. 5, all thin film transistors T1 to T6 are shown as being n-type thin film transistors.

However, the present disclosure is not limited thereto, and according to the embodiment, some of the thin film transistors T1 to T6 may be formed as p-type thin film transistors.

In addition, the n-type thin film transistor may be an oxide thin film transistor, and the p-type thin film transistor may be a polycrystalline silicon thin film transistor.

Hereinafter, a case where all thin film transistors T1 to T6 are n-type thin film transistors will be mainly described.

Therefore, the thin film transistors T1 to T6 are turned on by receiving a high voltage.

According to one example, the second transistor T2 forming the pixel circuit may serve as a driving transistor, the third transistor T3 may serve as a compensation transistor, the first thin film transistor may serve as a data supply transistor, the fourth and fifth transistors T4 and T5 may serve as emission control transistors, and the sixth transistor T6 may serve as an initialization transistor.

The light emitting element EL may include an anode and a cathode. The anode of the light emitting element EL may be connected to a second electrode of the fifth transistor T5, and the cathode thereof may be connected to the low potential driving voltage EVSS.

The second thin film transistor T2 may include a first electrode connected to a second electrode of the fourth transistor T4, a second electrode connected to a first electrode of the fifth transistor T5, and a gate electrode connected to a second electrode of the third transistor T3. The second thin film transistor T2 may provide a driving current to the light emitting element EL based on a data voltage stored in the capacitor CST.

The third thin film transistor T3 may include a first electrode connected to the second electrode of the fourth transistor T4, a second electrode connected to a gate electrode of the second thin film transistor T2, and a gate electrode for receiving a first scan signal SCAN1(n). The third thin film transistor T3 may be turned on in response to the first scan signal SCAN1(n) and diode-connected between the first electrode and the second electrode to sample a threshold voltage (Vth) of the second thin film transistor T2. The third thin film transistor T3 may be the compensation transistor.

The capacitor CST may be connected or formed between the second electrode of the third thin film transistor T3 (or the gate electrode of the second thin film transistor T2) and the anode of the light emitting element EL.

The first thin film transistor T1 may include a first electrode connected to the data line DL (or for receiving the data voltage DATA), a second electrode connected to the second electrode of the second thin film transistor T2 (or a first electrode of the fifth thin film transistor T5), and a gate electrode for receiving a second scan signal SCAN2(n). The first thin film transistor T1 may be turned on in response to the second scan signal SCAN2(n) and may transmit the data voltage DATA to the second electrode of the second thin film transistor T2 (or the first electrode of the fifth thin film transistor T5). The first thin film transistor T1 may be a data supply transistor.

The fourth thin film transistor T4 and the fifth thin film transistor T5 (or the first and second emission control transistors) may be connected to the high potential voltage line VDDEL, connected between the high potential driving voltage EVDD and the light emitting element EL, and may form a current movement path through which the driving current generated by the second thin film transistor T2 moves.

The fourth thin film transistor T4 may include a first electrode for receiving the high potential driving voltage EVDD, a second electrode connected to the first electrode of the second thin film transistor T2 (or the first electrode of the third thin film transistor T3), and a gate electrode for receiving an emission control signal EM(n).

The fifth thin film transistor T5 may include a first electrode connected to the second electrode of the second thin film transistor T2 (or the second electrode of the first thin film transistor T1), a second electrode connected to a second electrode of the sixth thin film transistor T6 (or the anode electrode of the light emitting element EL), and a gate electrode for receiving an emission control signal EM(n-1).

The fourth and fifth thin film transistors T4 and T5 may be turned on in response to the emission control signals EM(n) and EM(n-1), respectively, and in this case, the driving current may be provided to the light emitting element EL, and the light emitting element EL may emit light with brightness corresponding to the driving current. In FIG. 5, the fourth and fifth thin film transistors T4 and T5 are shown as being turned on in response to the emission control signals EM(n) and EM(n-1), respectively, but are not limited thereto, and the fourth and fifth thin film transistors T4 and T5 may be turned on in response to the same emission control signal EM(n).

The sixth thin film transistor T6 may include a first electrode for receiving an initialization voltage VINI, a second electrode connected to the anode of the light emitting element EL, and a gate electrode for receiving the first scan signal SCAN(n).

The sixth thin film transistor T6 may be turned on in response to the first scan signal SCAN(n) before the light emitting element EL emits light (or after the light emitting element EL emits light) and may initialize the anode (or a pixel electrode) of the light emitting element EL using the initialization voltage VINI. The light emitting element EL may have a parasitic capacitor formed between the anode electrode and the cathode electrode. In addition, while the light emitting element EL emits light, the parasitic capacitor may be charged so that the anode of the light emitting element EL may have a specific voltage. Therefore, the amount of charge accumulated in the light emitting clement EL may be initialized by applying the initialization voltage VINI to the anode of the light emitting element EL through the sixth thin film transistor T6.

FIG. 6 shows the connection relationship between the sixth thin film transistor T6, the fifth thin film transistor T5, and the second thin film transistor T2. While describing the cross-sectional view of the display device according to the fifth embodiment shown in FIG. 6, descriptions overlapping those in FIGS. 1 to 4 will be omitted. The sixth thin film transistor T6 may serve as an initialization transistor, the fifth thin film transistor T5 may serve as an emission control transistor, and the second thin film transistor T2 may serve as a driving transistor.

The second conductive layer 140 may include the light blocking layer 141 located under the semiconductor layers ACT6, ACT5, and ACT2 of the thin film transistors T6, T5, and T2, and the connection line CNE_2. The light blocking layer 141 and the second connection line CNE_2 may contain the same material.

The semiconductor layer may include the sixth semiconductor layer ACT6 of the sixth thin film transistor T6, the fifth semiconductor layer ACT5 of the fifth thin film transistor T5, and the second semiconductor layer ACT2 of the second thin film transistor T2, and the first connection line CNE_1. The sixth semiconductor layer ACT6 may include a channel area ACT61, a first area ACT62 overlapping and electrically connected to a source electrode SD6 to be described below, and a second area ACT63 electrically connected and directly connected to the first connection line CNE_1. The fifth semiconductor layer ACT5 may include a channel area ACT51, a second area ACT53 electrically connected and directly connected to the first connection line CNE_1, and a first area ACT52 overlapping and electrically connected to a source electrode SD5 to be described below. The first area ACT52 may be electrically connected to the second connection line CNE_2 through the source electrode SD5. The second semiconductor layer ACT2 may include a channel area ACT21, a first area ACT22 overlapping and electrically connected to a source electrode SD21 to be described below, and a second area ACT23 electrically connected to the second connection line CNE_2 and overlapping and electrically connected to the drain electrode SD22. The second area ACT23 may be electrically connected to the second connection line CNE_2 through the source electrode SD22.

The third conductive layer 150 may include a sixth gate electrode G6 of the sixth thin film transistor T6, a fifth gate electrode G5 of the fifth transistor T5, and a second gate electrode G2 of the second thin film transistor T2.

The fourth conductive layer 160 may include the source electrode SD6 of the sixth thin film transistor T6, the source electrode SD5 of the fifth thin film transistor T5, and the drain electrode SD22 and the source electrode SD21 of the second thin film transistor T2.

Meanwhile, FIG. 6 further shows structures above the fourth conductive layer 160 of the display device. The display device according to FIG. 6 may further include a planarization layer 128 disposed on the fourth conductive layer 160, a first electrode ANO disposed on the planarization layer 128, a bank layer 129 disposed on the first electrode ANO, an organic layer OL disposed on an upper surface of the first electrode ANO exposed by the bank layer 129, a second electrode CAT disposed on the organic layer OL, and an encapsulation layer 180 disposed on the second electrode CAT As shown in FIG. 6, the planarization layer 128 disposed on the fourth conductive layer 160, the first electrode ANO disposed on the planarization layer 128, the bank layer 129 disposed on the first electrode ANO, the organic layer OL disposed on the upper surface of the first electrode ANO exposed by the bank layer 129, the second electrode CAT disposed on the organic layer OL, and the encapsulation layer 180 disposed on the second electrode CAT may also be applied to the above-described display device according to FIGS. 1 to 4.

The planarization layer 128 may be disposed on the fourth conductive layer 160. The planarization layer 128 may contain an organic material. The planarization layer 128 may serve to planarize the fourth conductive layer 160.

The first electrode ANO may be disposed on the planarization layer 128. The first electrode ANO may serve as an anode of the display device. The bank layer 129 may be provided to cover an edge of the first electrode ANO. The emission area may be defined by the bank layer 129. The bank layer 129 may expose the upper surface of the first electrode ANO. The first electrode ANO may be electrically connected to the second area ACT53 of the fifth semiconductor layer ACT5 of the fifth thin film transistor T5 through a 5-3 contact hole CT53. However, the present disclosure is not limited thereto, and the first electrode ANO may be electrically connected to the second area ACT63 of the sixth semiconductor layer ACT6 of the sixth thin film transistor T6 through the contact hole.

The organic layer OL may be disposed on the upper surface of the first electrode ANO exposed by the bank layer 129. Although FIG. 6 shows that the organic layer OL is disposed only on the upper surface of the first electrode ANO exposed by the bank layer 129, the present disclosure is not limited thereto, and the organic layer OL may be integrally formed through the pixel P (scc FIG. 5).

The second electrode CAT is formed on the organic layer OL. The second electrode CAT may serve as a cathode of the display device. The second electrode CAT may be formed integrally throughout the pixel P (see FIG. 5).

The first electrode ANO, the organic layer OL, and the second electrode CAT may form an organic light emitting element EL.

The encapsulation layer 180 is formed on the second electrode CAT to prevent external moisture from permeating the organic layer OL. The encapsulation layer 180 may be made of an inorganic insulating material or may be formed in a structure in which an inorganic insulating material and an organic insulating material are alternately stacked, but is not necessarily limited thereto. For example, the encapsulation layer 180 may include a first encapsulation layer 181 and a third encapsulation layer 183 that contain an inorganic insulating material, and a second encapsulation layer 182 containing an organic insulating material between the first encapsulation layer 181 and the third encapsulation layer 183, but is not limited thereto.

The sixth thin film transistor T6 may include the sixth gate electrode G6, the first electrode, and the second electrode. The first electrode of the sixth thin film transistor T6 may be the first area ACT62 or the source electrode SD6. The second electrode of the sixth thin film transistor T6 may be the second area ACT63.

The fifth thin film transistor T5 may include the fifth gate electrode G5, the first electrode, and the second electrode. The first electrode of the fifth thin film transistor T5 may be the first area ACT52 or the source electrode SD5. The second electrode of the fifth thin film transistor T5 may be the second area ACT53.

The second thin film transistor T2 may include the second gate electrode G2, the first electrode, and the second electrode. The first electrode of the second thin film transistor T2 may be the first area ACT22 or the source electrode SD21. The second electrode of the second thin film transistor T2 may be the second area ACT23 or the drain electrode SD22.

The source electrode SD6 of the sixth thin film transistor T6 may be electrically connected to the first area ACT62 through a sixth contact hole CT6.

The source electrode SD5 of the fifth thin film transistor T5 may be electrically connected to the first area ACT52 through a 5-1 contact hole CT51 and electrically connected to the second connection line CNE_2 through a 5-2 contact hole CT52.

The source electrode SD21 of the second thin film transistor T2 may be electrically connected to the first area ACT22 through a 2-1 contact hole CT21, and the drain electrode SD22 may be electrically connected to the second area ACT23 through a 2-2 contact hole CT22 and electrically connected to the second connection line CNE_2 through a 2-3 contact hole CT23.

According to the fifth embodiment, the electrical connection method between the sixth thin film transistor T6 and the fifth thin film transistor T5 may differ from the electrical connection method between the fifth thin film transistor T5 and the second thin film transistor T2. In the present embodiment, the sixth thin film transistor T6 and the fifth thin film transistor T5 may be electrically connected through the first connection line CNE_1 located coplanarly with the semiconductor layer, and the fifth thin film transistor T5 and the second thin film transistor T2 may be electrically connected through the second connection line CNE_2 located on the second conductive layer 140.

In the present embodiment, the second thin film transistor T2 and the third thin film transistor T3 may be sensitive to fluctuation of the threshold voltage (Vth). In the present specification, when some thin film transistors (e.g., T2 and T3) are sensitive to fluctuation of threshold voltage (Vth) compared to other thin film transistors T1 and T4 to T6, it means that when the fluctuation of the threshold voltage (Vth) from the initially set threshold voltages (Vth) of the thin film transistors T2 and T3 is caused by light, temperature, hydrogen, etc., fluctuation of luminance of the light emitting element EL is caused by the corresponding fluctuation, and the magnitude of the fluctuation relatively greatly occurs compared to other thin film transistors T1 and T4 to T6. For example, while each of the thin film transistors T2 and T3 may have a change rate of a driving current Ioled of 31 3.44 to 13.68% and −6.09 to 8.26%, respectively, with respect to a reference driving current at the threshold voltage (Vth) of −0.5 to 0.5 V, other thin film transistors T1 and T4 to T6 may have a change rate of a driving current Ioled of −0.08 to 0.23%, −0.09 to 0.05%, −0.45 to 0.01%, and −0.6 to 1.29%, respectively, with respect to the reference driving current at the threshold voltage (Vth) of −0.5 to 0.5 V.

Therefore, to electrically connect the second thin film transistor T2 sensitive to the fluctuation of the threshold voltage (Vth) with the adjacent fifth thin film transistor T5, the second connection line CNE_2 of the second conductive layer 140 having a higher reflectance than the semiconductor layer may be applied. Therefore, it is possible to prevent the phenomenon in which light enters the connection line CNE_2 and travels inside the connection line CNE_2, thereby preventing changes in characteristics of the second thin film transistor T2 due to light and preventing degradation of reliability thereof.

Furthermore, the first and fourth to sixth thin film transistors T1 and T4 to T6 may be less sensitive to the fluctuation of the threshold voltage (Vth) compared to the second and third thin film transistors T2 and T3. Therefore, in the process of electrically connecting the sixth and fifth thin film transistors T6 and T5, to simplify the process rather than considering changes in characteristics of the thin film transistors T5 and T6 due to light, it is more effective to reduce the contact hole between the source/drain electrodes and the semiconductor layers ACT6 and ACT5. The second electrode ACT63 of the sixth semiconductor layer ACT6 of the sixth thin film transistor T6 and the second electrode ACT53 of the fifth semiconductor layer ACT5 of the fifth thin film transistor T5 may be electrically connected by being directly connected to the coplanarly located first connection line CNE_1.

In the present embodiment, the second thin film transistor T2 and the third thin film transistor T3 may be sensitive to fluctuation of the threshold voltage (Vth). Therefore, to electrically connect the second thin film transistor T2 sensitive to the fluctuation of the threshold voltage (Vth) with the adjacent fifth thin film transistor T5, the second connection line CNE_2 of the second conductive layer 140 having higher reflectance than the semiconductor layer may be applied. Therefore, it is possible to prevent the phenomenon in which light enters the connection line CNE_2 and travels inside the connection line CNE_2, thereby preventing changes in characteristics of the second thin film transistor T2 due to light and preventing degradation of reliability thereof.

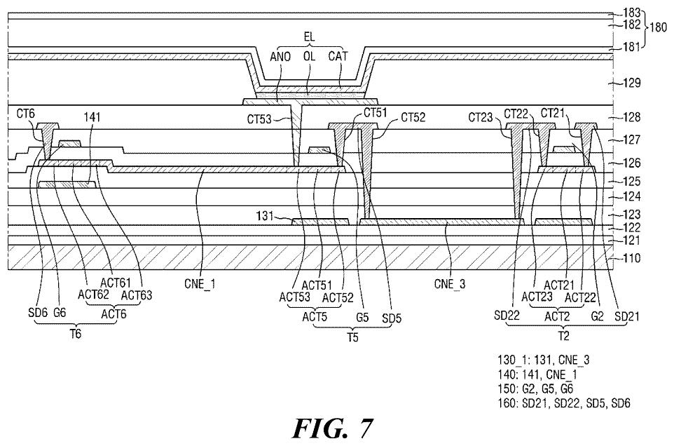

FIG. 7 is a cross-sectional view of a modified example of the display device according to FIG. 6.

Referring to FIG. 7, the modified example differs from the embodiment according to FIG. 6 in that the fifth thin film transistor T5 and the second thin film transistor T2 of the display device according to the present embodiment may be electrically connected through the third connection line CNE_3.

Since description of the third connection line CNE_3 has been described above in the connection line CNE_3 of FIG. 4, detailed description thereof will be omitted below. In the embodiment according to FIG. 7, the first conductive layer 130_1 may include light blocking layers 131 respectively located under the semiconductor layers ACT5 and ACT2 of the thin film transistors T5 and T2, and a connection line CNE_3. That is, unlike the light blocking layer 141 of the sixth thin film transistor T6, in the fifth thin film transistor T5 and the second thin film transistor T2, the light blocking layer 131 may be disposed in the first conductive layer 130_1. The light blocking layer 131 and the third connection line CNE_3 may include the same material.

Although the embodiments of the present disclosure have been described above with reference to the accompanying drawings, those skilled in the art to which the present disclosure pertains will be able to understand that the above-described technical configuration of the present disclosure can be carried out in other specific forms without changing the technical spirit or essential features thereof. Therefore, it should be understood that the above-described embodiments are illustrative and not restrictive in all respects. In addition, the scope of the present disclosure is described by the claims to be described below rather than the detailed description. In addition, the meaning and scope of the claims and all changed or modified forms derived from the equivalent concept should be construed as being included in the scope of the present disclosure.

### DESCRIPTION OF REFERENCE NUMERALS

1: display device
200: controller
300: gate driver
310: scan driver
320: emission control signal driver

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a first thin film transistor, a second thin film transistor, and a third thin film transistor, each of the first thin film transistor, the second thin film transistor, and the third thin film transistor including:
a semiconductor layer,
a gate electrode on the semiconductor layer, and
a first electrode and a second electrode adjacent to the gate electrode;
a first connection line between the first thin film transistor and the second thin film transistor; and
a second connection line between the second thin film transistor and the third thin film transistor,
wherein connection between the semiconductor layer of the first thin film transistor and the semiconductor layer of the second thin film transistor via the first connection line differs from connection between the semiconductor layer of the second thin film transistor and the semiconductor layer of the third thin film transistor via the second connection line.

2. The display device of claim 1, wherein the semiconductor layer of the first thin film transistor, the semiconductor layer of the second thin film transistor, and the semiconductor layer of the third thin film transistor each include an oxide.

3. The display device of claim 1, wherein the semiconductor layer of the first thin film transistor and the semiconductor layer of the second thin film transistor are electrically connected through the first connection line located coplanarly with the semiconductor layer.

4. The display device of claim 3, wherein the semiconductor layer and the first connection line include a same material.

5. The display device of claim 3, wherein a first scan signal is applied to the gate electrode of the first thin film transistor, an initialization voltage is applied to the first electrode of the first thin film transistor, and the second electrode of the first thin film transistor is electrically connected to the first electrode of the second thin film transistor.

6. The display device of claim 5, wherein the first thin film transistor is an initialization transistor.

7. The display device of claim 3, wherein an emission control signal is applied to the gate electrode of the second thin film transistor, the first electrode of the second thin film transistor is electrically connected to the second electrode of the first thin film transistor, and the second electrode of the second thin film transistor is electrically connected to the second electrode of the third thin film transistor.

8. The display device of claim 7, wherein the second thin film transistor is an emission control transistor.

9. The display device of claim 1, wherein the semiconductor layer of the second thin film transistor and the semiconductor layer of the third thin film transistor are electrically connected through the second connection line located at a different layer from the semiconductor layer.

10. The display device of claim 9, wherein the second connection line is disposed under the semiconductor layer.

11. The display device of claim 9, wherein the semiconductor layer of the second thin film transistor and the first connection line are electrically connected through the second electrode of the second thin film transistor, and the semiconductor layer of the third thin film transistor and the second connection line are electrically connected to the second electrode of the third thin film transistor.

12. The display device of claim 1, wherein a first scan signal is applied to the gate electrode of the first thin film transistor, an initialization voltage is applied to the first electrode of the first thin film transistor, and the second electrode of the first thin film transistor is electrically connected to the first electrode of the second thin film transistor.

13. The display device of claim 12, wherein the first thin film transistor is an initialization transistor.

14. The display device of claim 1, wherein an emission control signal is applied to the gate electrode of the second thin film transistor, the first electrode of the second thin film transistor is electrically connected to the second electrode of the first thin film transistor, and the second electrode of the second thin film transistor is electrically connected to the second electrode of the third thin film transistor.

15. The display device of claim 14, wherein the second thin film transistor is an emission control transistor.

16. The display device of claim 1, further comprising a capacitor disposed between the second electrode of the first thin film transistor and the third thin film transistor.

17. The display device of claim 16, wherein the gate electrode of the third thin film transistor is electrically connected to the capacitor, a high potential voltage is applied to the first electrode of the third thin film transistor, and the second electrode of the third thin film transistor is electrically connected to the second electrode of the second thin film transistor.

18. The display device of claim 17, wherein the third thin film transistor is a driving transistor.

19. A display device, comprising:
a substrate;
a first thin film transistor, a second thin film transistor, and a third thin film transistor on the substrate, the first thin film transistor, the second thin film transistor, and the third thin film transistor each including:
a semiconductor layer,
a gate electrode on the semiconductor layer, and
a first electrode and a second electrode adjacent to the gate electrode;
a first connection line, the semiconductor layer of the first thin film transistor and the semiconductor layer of the second thin film transistor being electrically connected through the first connection line; and
a second connection line, the semiconductor layer of the second thin film transistor and the semiconductor layer of the third thin film transistor being electrically connected through the second connection line,
wherein a reflectance of the first connection line is lower than a reflectance of the second connection line. 20 The display device of claim 19, wherein the first connection line is located coplanarly with the semiconductor layer, and the second connection line is located under the semiconductor layer.

21. A display device, comprising:
a substrate;
a first thin film transistor and a second thin film transistor adjacent to the first thin film transistor on the substrate;
a connection line between the first thin film transistor and the second thin film transistor, the connection line electrically connecting the first thin film transistor and the second thin film transistor;
a light emitting element electrically connected to at least one of the first thin film transistor and the second thin film transistor;
wherein the first thin film transistor and the second thin film transistor each includes:
a semiconductor layer on a first layer,
a gate electrode on a second layer, and
a first electrode and a second electrode adjacent to the gate electrode, the first electrode and the second electrode on a third layer,
wherein the connection line electrically connecting the first thin film transistor and the second thin film transistor is on a different layer from the first, second, and third layers.

22. The display device of claim 21, further comprising:
a light blocking layer overlapping the semiconductor layer of either the first thin film transistor or the second thin film transistor,
wherein the connection line is on a same layer as the light blocking layer.

23. The display device of claim 22, wherein the connection line is spaced apart from the light blocking layer from a plan view,
wherein the light blocking layer and the connection line are made of a same material.

24. The display device of claim 22, wherein the connection line electrically connects the first electrode of the first thin film transistor and the first electrode of the second thin film transistor,
wherein the connection line overlaps with the first electrode of the first thin film transistor and the first electrode of the second thin film transistor from a plan view, and
wherein the connection line does not overlap with the second electrode of the first thin film transistor and the second electrode of the second thin film transistor from a plan view.

25. The display device of claim 21, further comprising:
a light blocking layer overlapping the semiconductor layer of either the first thin film transistor or the second thin film transistor,
wherein the connection line is on a different layer as the light blocking layer.

26. The display device of claim 25, wherein the connection line is closer to the substrate than the light blocking layer.

27. The display device of claim 25, wherein the light blocking layer is closer to the substrate than the connection line.

28. The display device of claim 25, wherein the connection line is spaced apart from the light blocking layer from a plan view,
wherein the light blocking layer and the connection line are made of a different material.

29. The display device of claim 25, wherein the connection line electrically connects the first electrode of the first thin film transistor and the first electrode of the second thin film transistor,
wherein the connection line overlaps with the first electrode of the first thin film transistor and the first electrode of the second thin film transistor from a plan view, and
wherein the connection line does not overlap with the second electrode of the first thin film transistor and the second electrode of the second thin film transistor from a plan view.

30. A display device, comprising:
a substrate;
a first thin film transistor and a second thin film transistor adjacent to the first thin film transistor on the substrate;
a connection line on the substrate and between the first thin film transistor and the second thin film transistor from a plan view, the connection line electrically connecting the first thin film transistor and the second thin film transistor, the connection line and the substrate being spaced apart from each other by a first distance;
a light emitting element electrically connected to at least one of the first thin film transistor and the second thin film transistor;
wherein the first thin film transistor and the second thin film transistor each includes:
a semiconductor layer on the substrate, the semiconductor layer and the substrate being spaced apart from each other by a second distance,
a gate electrode adjacent to the semiconductor layer, and
a first electrode and a second electrode adjacent to the gate electrode,
wherein the second distance is different from the first distance.

31. The display device of claim 30, wherein the first distance is shorter than the second distance such that the connection line is closer to the substrate than the semiconductor layer of either the first thin film transistor or the second thin film transistor.

32. The display device of claim 30, wherein the connection line and the semiconductor layer of the first thin film transistor and the second thin film transistor are on a same layer.
